(19) United States
(12) Patent Application Publication
(10) Pub. No.: US 2014/0035030 A1
(43) Pub. Date: Feb. 6, 2014

(54) SEMICONDUCTOR DEVICE

(71) Applicant: KABUSHIKI KAISHA TOSHIBA, Tokyo (JP)

(72) Inventors: Masaaki OGAWA, Kanagawa-ken (JP); Toshifumi NISHIGUCHI, Ishikawa-ken (JP); Tsuyoshi OTA, Hyogo-ken (JP)

(21) Appl. No.: 13/781,649

(22) Filed: Feb. 28, 2013

(30) Foreign Application Priority Data
Aug. 6, 2012 (JP) 2012-174361

(51) Int. Cl. H01L 29/78; H01L 21/36

(52) U.S. Cl. CPC H01L 29/7827; H01L 21/36
USPC 257/330; 438/478

(57) ABSTRACT

According to one embodiment, in a semiconductor device, a semiconductor laminated body includes a first semiconductor region of a first conductivity type and a second semiconductor region of the first conductivity type provided on the first semiconductor region and having a higher concentration of impurities than that of the first semiconductor region. A third semiconductor region includes a side surface and a lower end, the side surface and the lower end are surrounded by the semiconductor laminated body. A fourth semiconductor region of a second conductivity type is provided between the semiconductor laminated body and the third semiconductor region. A fifth semiconductor region of the first conductivity type is in contact with an outside surface of the semiconductor laminated body opposite to an inside surface of the semiconductor laminated body, the inside surface is in contact with the fourth semiconductor region.

### CROSS REFERENCE TO RELATED APPLICATION

This application is based upon and claims the benefit of priority from the prior Japanese Patent Application No. 2012-174361, filed on Aug. 6, 2012, the entire contents of which are incorporated herein by reference.

### FIELD

Embodiments described herein relate generally to a semiconductor device.

### BACKGROUND

As a power MOSFET, there are a MOSFET having a planar structure and a MOSFET having a trench structure. In the MOSFET having a planar structure, a predetermined voltage is applied to a gate electrode so as to generate an inversion layer on a surface of a base region, so that electric current flows to a semiconductor substrate in a horizontal direction.

Meanwhile, in the MOSFET having a trench structure, a predetermined voltage is applied to a trench gate electrode which is provided in a vertical direction to a substrate so as to generate an inversion layer on a base region opposite to the gate electrode, so that electric current flows to a semiconductor substrate in a longitudinal direction.

On the other hand, a MOSFET having a three-dimensional structure captures attention as a power MOSFET capable of flowing higher electric current.

Further, in the above-described MOSFET having a three-dimensional structure, improvement of withstand voltage and a low cost are desired.

### BRIEF DESCRIPTION OF THE DRAWINGS

FIG. 1 is a schematic perspective view illustrating a semiconductor device according to a first embodiment;

FIGS. 2A and 2B are schematic views illustrating the semiconductor device according to a first embodiment;

FIG. 2A is the schematic plan view;

FIG. 2B is the schematic cross-sectional view;

FIGS. 3A and 3B, 4A and 4B, 5A and 5B, 6A and 6B, 7A and 7B are schematic views illustrating steps of manufacturing the semiconductor device in sequential order according to the first embodiment;

FIG. 8 is a schematic perspective view illustrating a semiconductor device according to a first reference example;

FIGS. 9A to 9C, 10A and 10B are schematic views illustrating steps of manufacturing the semiconductor device in sequential order according to the first reference example;

FIGS. 11A to 11C are schematic views illustrating steps of manufacturing the semiconductor device in sequential order according to a second reference example; and

FIGS. 12A and 12B are schematic perspective views illustrating the semiconductor device according to the second reference example.

### DETAILED DESCRIPTION

According to one embodiment, in a semiconductor device, a semiconductor laminated body includes a first semiconductor region of a first conductivity type and a second semiconductor region of the first conductivity type provided on the first semiconductor region and having a higher concentration of impurities than that of the first semiconductor region. The semiconductor laminated body includes an inside surface and an outside surface opposed to the inside surface. The first semiconductor region includes an upper surface and a lower surface. A third semiconductor region includes a side surface and a lower end, the side surface and the lower end are surrounded by the semiconductor laminated body. A fourth semiconductor region of a second conductivity type is provided between the semiconductor laminated body and the third semiconductor region. The fourth semiconductor region is in contact with the inside surface of the semiconductor laminated body, and includes an upper end and a lower end. A fifth semiconductor region of the first conductivity type is in contact with the outside surface of the semiconductor laminated body. A first electrode being in contact with the third semiconductor region, the fourth semiconductor region and the second semiconductor region via a first insulating film, and including a lower end. A second electrode provided between the fourth semiconductor region and the fifth semiconductor region, and includes a side surface and a lower surface. The side surface is in contact with the semiconductor laminated body via a second insulating film. A third electrode is electrically connected to the third semiconductor region. A fourth electrode is electrically connected to the fifth semiconductor region. The lower end of the second electrode is positioned between the lower surface of the first semiconductor region and the upper surface of the first semiconductor region. The upper surface of the first semiconductor region is positioned between the lower end of the third semiconductor region and the lower end of the fourth semiconductor region.

Hereinafter, embodiments will be described with reference to the drawings. In the drawings, same reference characters denote the same or similar portions.

### First Embodiment

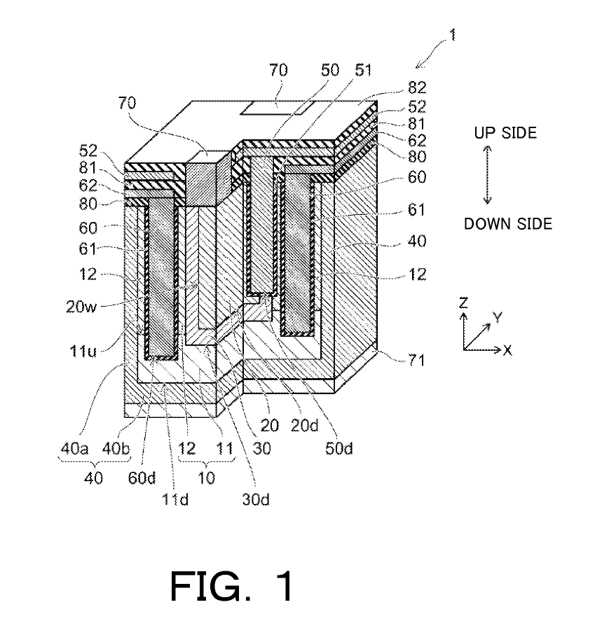

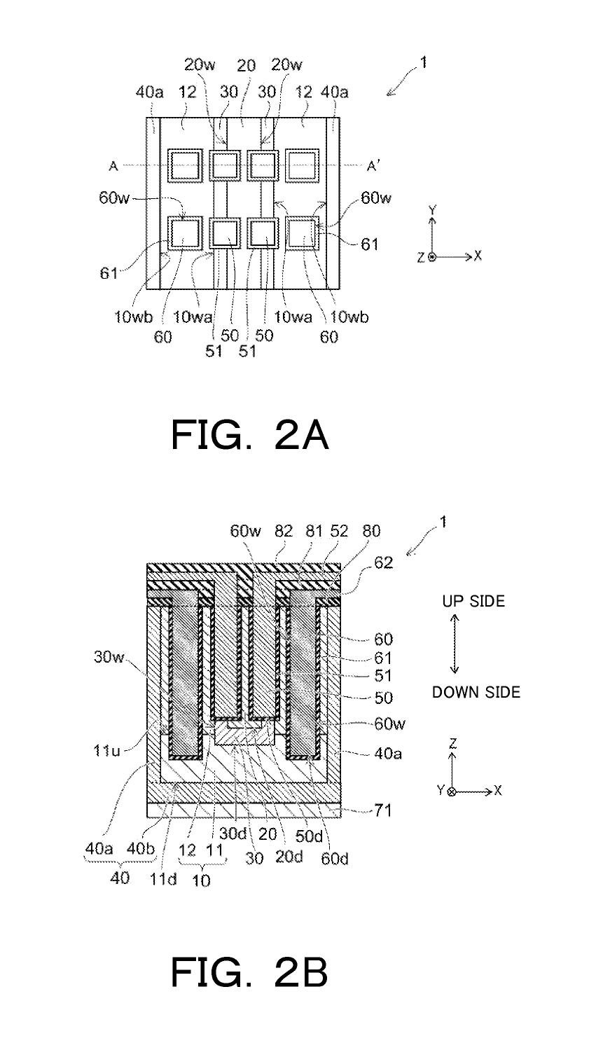

FIG. 1 is a schematic perspective view of a semiconductor device in accordance with a first embodiment. FIGS. 2A and 2B are schematic views of the semiconductor device in accordance with the first embodiment. FIG. 2A is a schematic plan view and FIG. 2B is a schematic cross-sectional view.

FIG. 1 represents a state in which a portion of a surface of a semiconductor device 1 is eliminated in order to illustrate an inside structure of the semiconductor device 1.

FIG. 2A is a plane of the semiconductor device 1 when a space between an upper end of a base region and a lower end of a gate electrode 50 is cut taken along the X-Y plane in FIG. 1. FIG. 2B illustrates a cross section taken along the A-A′ line in FIG. 2A.

The semiconductor device 1 in accordance with the first embodiment is the MOSFET having a three-dimensional structure. The semiconductor device 1 includes a semiconductor laminated body 10. The semiconductor laminated body 10 includes an n⁻-type low concentration region (a first semiconductor region) 11 and an n⁻-type drift region (a second semiconductor region) 12 provided on the low concentration region 11. The concentration of impurities (dopant) included in the drift region 12 is higher than a concentration of impurities included in the low concentration region 11. In addition, a specific resistance of the low concentration region 11 is higher than a specific resistance of the drift region 12.

Further, the semiconductor device 1 includes an n⁺-type source region (a third semiconductor region) 20, a p-type base region (a fourth semiconductor region) 30 and an n⁺-type drain region 40a. The source region 20 includes a side surface 20w and a lower end 20d, and the side surface 20w and the lower end 20d of the source region 20 are surrounded by the semiconductor laminated body 10. The base region 30 is provided between the semiconductor laminated body 10 and the source region 20. The source region 20 and the base region 30 are extended in a Y direction. The drain region 40a is in contact with an outside surface 10wb of the semiconductor laminated body 10 opposite to an inside surface 10wa of the semiconductor laminated body 10 which is in contact with the base region 30.

FIG. 1 illustrates an n⁺-type drain region 40b provided below the semiconductor laminated body 10, in addition to the drain region 40a which is in contact with the outside surface 10wb of the semiconductor laminated body 10. The drain region 40a is adjacent to the drain region 40b to integrate drain region (a fifth semiconductor region) 40. That is, the semiconductor laminated body 10 is surrounded by the drain region 40. In addition, in the first embodiment, a laminated body, which includes the drain region 40b, the low concentration region 11 provided on the drain region 40b, and the drift region 12 provided on the low concentration region 11, may be referred to as the semiconductor laminated body 10.

Further, the semiconductor device 1 includes a gate electrode (a first electrode) 50 and a field plate electrode 60 (a second electrode). The gate electrode 50 is in contact with the source region 20, the base region 30 and drift region 12 through a gate insulating film (a first insulating film) 51. The gate electrode 50 is connected to a gate wiring 52. The field plate electrode 60 is provided between the base region 30 and the drain region 40a. A side surface 60w of the field plate electrode 60 is in contact with the semiconductor laminated body 10 through a field plate insulating film (a second insulating film) 61. The field plate electrode 60 is connected to a field plate wiring 62.

Further, in the semiconductor device 1, a source electrode (a third electrode) 70 is electrically connected to the source region 20 and the base region 30. A drain electrode (a fourth electrode) 71 is electrically connected to the drain region 40. The field plate electrode 60 may be connected to the source electrode 70 through the field plate wiring 62.

Further, interlayer insulating films 80, 81, 82 are provided on the drain region 40a, the drift region 12, the base region 30, and the source region 20. The interlayer insulating film 80 is provided between the field plate wiring 62, the drain region 40a and the drift region 12. The interlayer insulating film 81 is provided between the field plate wire 62 and the gate wiring 52. The interlayer insulating film 82 covers the gate wiring 52.

In addition, FIGS. 1, 2A and 2B illustrate a state in which a lower end 60d of the field plate electrode 60 is positioned between a lower surface 11d of the low concentration region 11 and an upper surface 11u of the low concentration region 11. In other words, the lower end 60d of the field plate electrode 60 is positioned inside the low concentration region 11. However, a state of the semiconductor device 1 in accordance with the first embodiment is not limited to the state described above.

For example, the lower end 60d of the field plate electrode 60 may be positioned above the upper surface 11u of the low concentration region 11. In this case, the lower end 60d of the field plate electrode 60 is positioned inside the drift region 12. Further, the lower end 60d of the field plate electrode 60 may be positioned below the lower surface 11d of the low concentration region 11. In this case, the lower end 60d of the field plate electrode 60 is positioned inside the drain region 40a.

Further, FIGS. 1, 2A and 2B show a state in which the upper surface 11u of the low concentration region 11 is positioned between the lower end 20d of the source region 20 and the lower end 30d of the base region 30. However, the state of the semiconductor device 1 in accordance with the first embodiment is not limited to the state described above. For example, the upper surface 11u of the low concentration region 11 may be positioned above the lower end 20d of the source region 20.

Further, FIGS. 1, 2A and 2B show a state in which the lower end 50d of the gate electrode 50 is positioned above the lower end 60d of the field plate electrode 60. Further, FIGS. 1, 2A and 2B illustrate a state in which the lower end 50d of the gate electrode 50 is positioned above the lower end 20d of the source region 20. However, the state of the semiconductor device 1 in accordance with the first embodiment is not limited to the state described above. For example, the lower end 50d of the gate electrode 50 may be positioned between the lower end 20d of the source region 20 and the lower end 30d of the base region 30. In addition, the lower end 50d of the gate electrode 50 may be positioned below the lower end 30d of the base region 30.

In addition, for reducing a parasitic capacitance between the gate electrode 50 and the source region 20, it is preferable that the gate wiring 52 and the source region 20 (or the source electrode 70) overlap with each other as little as possible when the semiconductor device 1 is seen from a Z direction. Alternatively, it is preferable that a thickness of the insulating film (interlayer insulating films 80, 81) provided between the gate wiring 52 and the source region 20 be as thick as possible.

A main component of the low concentration region 11, the drift region 12, the source region 20, the base region 30 and the drain region 40 is silicon (Si), for example. A material of the gate electrode 50 and the field plate electrode 60 is a polysilicon doped with impurities or amorphous silicon doped with impurities, for example. A material of the gate insulating film 51 and the field plate insulating film 61 is oxide silicon (SiO₂), for example. A material of the source electrode 70 and the drain region 40 is metal.

Among a notation of an n⁻-type, an n⁻-type, and an n⁺-type, the n⁻-type means the lowest concentration of impurities, and the n⁺-type means the highest concentration of impurities. The n⁻-type, the n⁻-type, and the n⁺-type may be referred to as a first conductivity type. Further, a p-type and a p⁺-type may be referred to as a second conductivity type. The p⁺-type means a higher concentration of impurities than that of the p-type. As an element of impurities in the first conductivity type, arsenic (As), phosphorus (P) or the like is exemplified. As an element of impurities in the second conductivity type, boron (B) is exemplified.

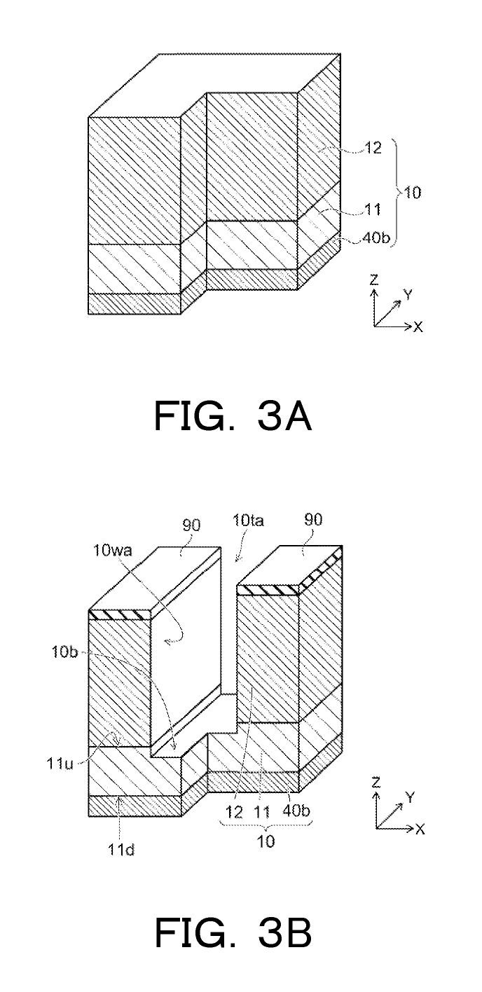

A manufacturing step of the semiconductor device 1 will be described. FIGS. 3A to 7B represent schematic perspective views illustrating steps of manufacturing the semiconductor device in accordance with the first embodiment.

Firstly, as illustrated in FIG. 3A, the semiconductor laminated body 10, which includes the drain region 40b, the low concentration region 11 and the drift region 12, is prepared. The low concentration region 11 is a semiconductor crystalline layer formed in advance on the drain region 40b by using epitaxial growth techniques. The drift region 12 is a semiconductor crystalline layer formed in advance on the low concentration region 11 by using epitaxial growth techniques. The semiconductor laminated body 10 illustrated in FIG. 3A is a semiconductor wafer including a three-layered semiconductor region.

In the first embodiment, a process treatment is carried out on the semiconductor laminated body 10 in which the low concentration region 11 and the drift region 12 are provided on the drain region 40b in advance.

As illustrated in FIG. 3B, a trench 10ta is formed in the semiconductor laminated body 10. For example, after patterning of a mask 90 on the semiconductor laminated body 10, an etching treatment is performed with respect to the semiconductor laminated body 10 opened by the mask 90. The etching treatment is an RIE (Reactive Ion Etching), for example. In this stage, a bottom surface 10b of the trench 10ta is adjusted so as to be positioned between the upper surface 11u and the lower surface 11d of the low concentration region 11. The bottom surface 10b is adjacent to the exposed inside surface 10wa of the semiconductor laminated body 10.

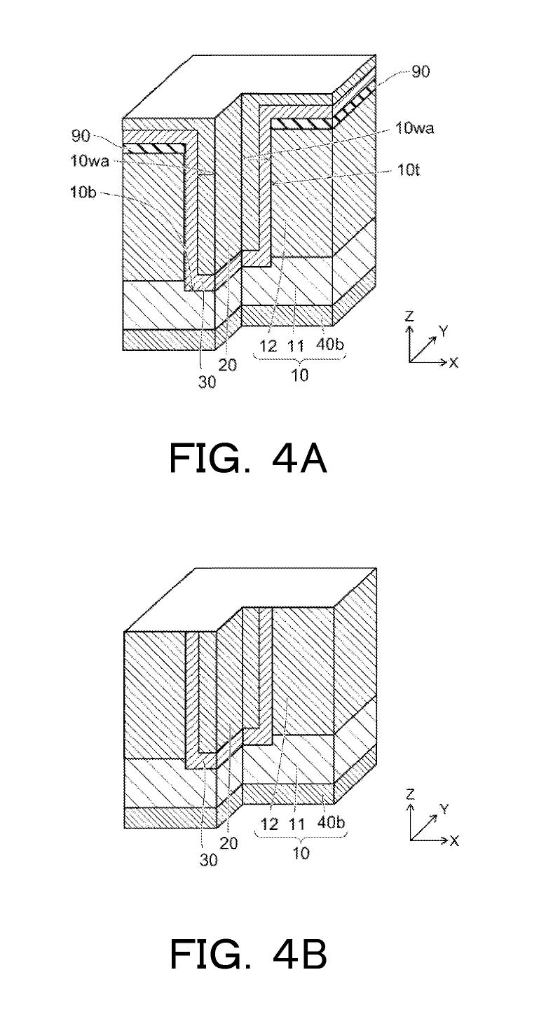

As illustrated in FIG. 4A, the base region 30 and the source region 20 are formed in the order, on the bottom surface 10b and the inside surface 10wa of the trench 10ta. The base region 30 and the source region 20 are formed by using epitaxial growth techniques. The base region 30 and the source region 20 are also formed on the mask 90. In the stage, a state in which the base region 30 is in contact with the inside surface 10wa of the semiconductor laminated body 10 is obtained.

As illustrated in FIG. 4B, a surplus portion of each of the mask 90, and the base region 30 and the source region 20 formed on the mask 90 is removed by a CMP (Chemical Mechanical Polishing). As a result, the upper surfaces of each of the drift region 12, the base region 30, and the source region 20 are flush with each other.

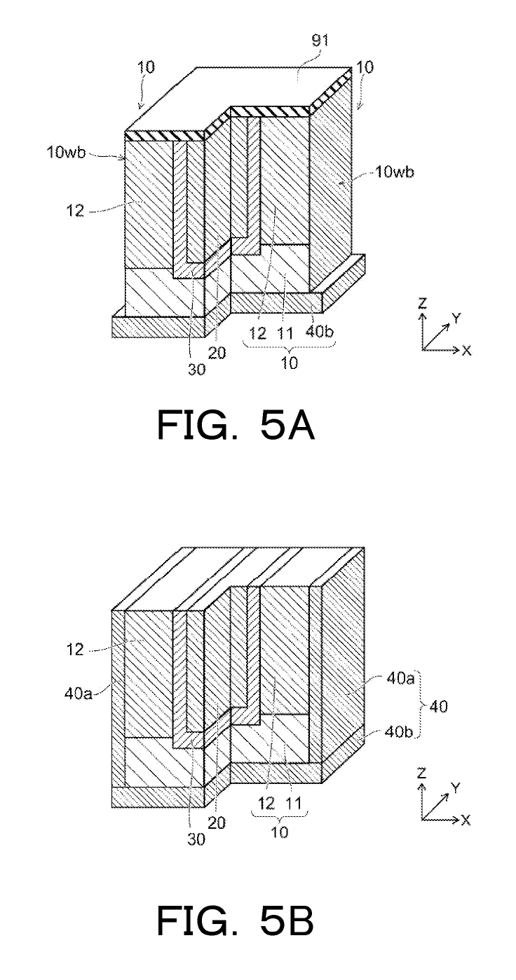

As illustrated in FIG. 5A, a trench 10tb is formed in the semiconductor laminated body 10. For example, after patterning of a mask 91 on the semiconductor laminated body 10, the etching treatment is performed to the semiconductor laminated body 10 opened from the mask 91. The etching treatment is RIE, for example. In the stage, a depth of the trench 10tb is adjusted such that the drain region 40b is exposed from a bottom portion of the trench 10tb. In addition, the outside surface 10wb of the semiconductor laminated body 10 is exposed by providing the trench 10tb. The outside surface 10wb is positioned at a position opposite to the inside surface 10wa described above.

The drain region 40a is formed inside the trench 10tb. Further, a surplus portion of the mask 91 and the drain region 40a is removed by the CMP. FIG. 5B illustrates the state.

As illustrated in FIG. 5B, in the stage, the drain region 40 in which the drain region 40a is integrated with the drain region 40b is formed. The drain region 40a is formed by using epitaxial growth techniques, a CVD (Chemical Vapor Deposition) method or the like, for example. The drain region 40a is in contact with the outside surface 10wb of the semiconductor laminated body 10.

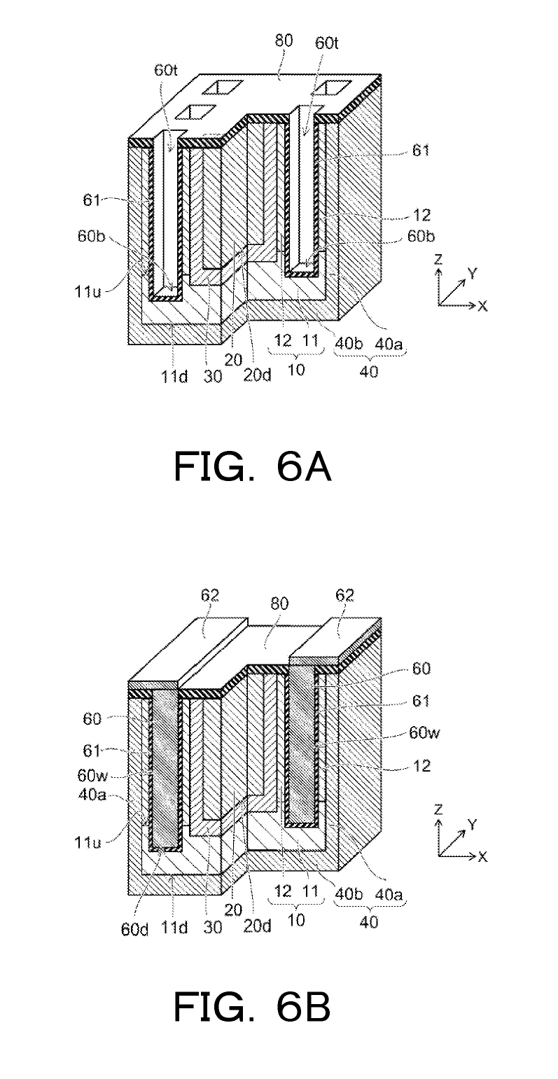

As illustrated in FIG. 6A, the interlayer insulating film 80 is patterned on the drain region 40a, the drift region 12, the base region 30, and the source region 20. Further, the etching treatment is carried out in the semiconductor laminated body 10 opened from the interlayer insulating film 80, and the trench 60t is formed in the semiconductor laminated body 10. Subsequently, the field plate insulating film 61 is formed in an inside wall of the trench 60t by using a thermal oxidation method.

In the stage, the interlayer insulating film 80 functions as the mask in the etching treatment. The trench 60t is formed between the base region 30 and the drain region 40a. Further, the bottom surface 60b of the trench 60t is adjusted so as to be positioned between the lower surface 11d of the low concentration region 11 and the upper surface 11u of the low concentration region 11.

As illustrated in FIG. 6B, the field plate electrode 60 is formed inside the trench 60t. In order to accelerate crystallinity of the field plate electrode 60, a heat treatment may be carried out to the field plate electrode 60 as necessary. Further, the field plate wiring 62 connected to the field plate electrode 60 is patterned on the interlayer insulating film 80. The field plate electrode 60 is formed by using the CVD method or the like, for example. The field plate electrode 60 is formed between the base region 30 and the drain region 40a.

As a result, a state in which the side surface 60w of the field plate electrode 60 is in contact with the semiconductor laminated body 10 through the field plate insulating film 61 may be obtained. Further, the lower end 60d of the field plate electrode 60 is positioned between the lower surface 11d of the low concentration region 11 and the upper surface 11u of the low concentration region 11.

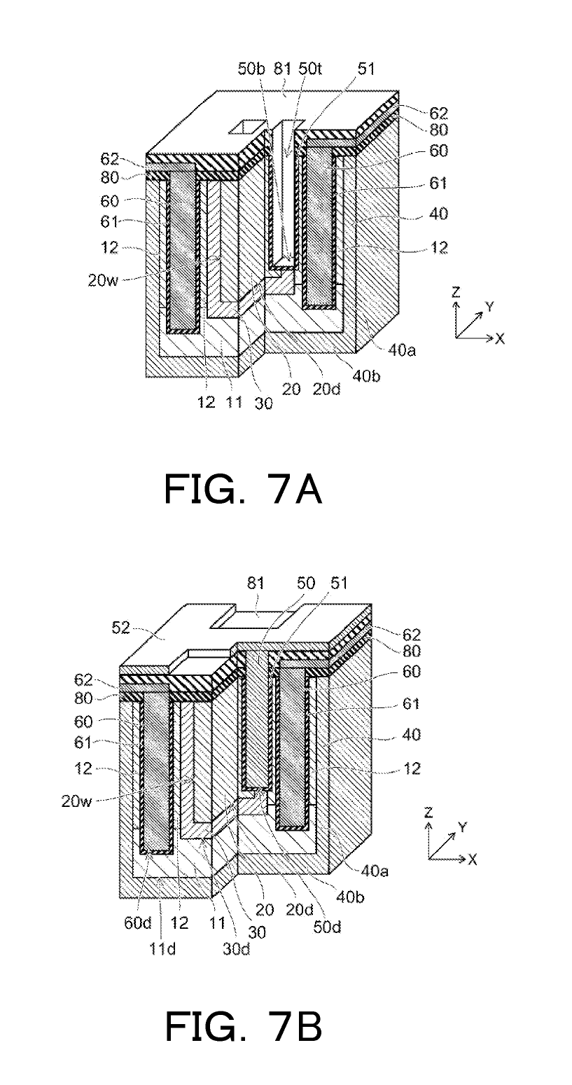

As illustrated in FIG. 7A, the interlayer insulating film 81 is patterned on the interlayer insulating film 80 and the field plate wiring 62. Thereafter, the etching treatment is carried out in the semiconductor laminated body 10 opened from the interlayer insulating film 80, and a trench 50t is formed in the semiconductor laminated body 10. Subsequently, the gate insulating film 51 is formed in the inside wall of the trench 50t by using the thermal oxidation method.

In the stage, the interlayer insulating film 81 functions as the mask in the etching treatment. Further, the gate insulating film 51 provided inside the trench 50t is in contact with the source region 20, the base region 30, and the drift region 12, respectively. In addition, the bottom surface 50b of the trench 50t is adjusted so as to be positioned above the lower end 20d of the source region 20.

As illustrated in FIG. 7B, the gate electrode 50 is formed inside the trench 50t. In order to accelerate the crystallinity of the gate electrode 50, the heat treatment may be carried out, in the gate electrode 50, as necessary. Further, a patterning of the gate wiring 52 connected to the gate electrode 50 is performed on the interlayer insulating film 81. The gate electrode 50 is formed by using the CVD method or the like, for example. In the stage, a state in which the gate electrodes 50 is in contact with each of the source region 20, the base region 30 and the drift region 12 through the gate insulating film 51, may be obtained. In addition, the lower end 50d of the gate electrode 50 is positioned above the lower end 20d of the source region 20.

Subsequently, as illustrated in FIGS. 1, 2A and 2B, the interlayer insulating film 82, the source electrode 70 electrically connected to the source region 20, and the drain electrode 71 electrically connected to the drain region 40 are formed.

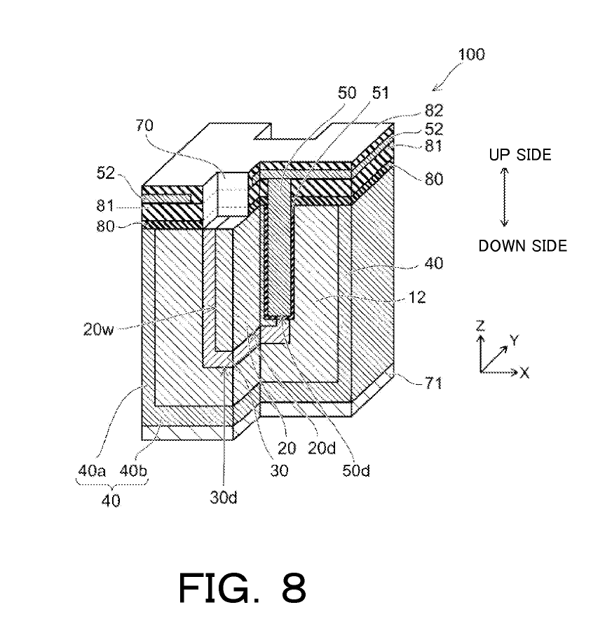

Before an advantage of the first embodiment is described, a first reference example and a second reference example will be described. FIGS. 8A and 8B illustrate schematic perspective views of the semiconductor device in accordance with the first reference example.

The above-described low concentration region 11 and the field plate electrode 60 are not provided in a semiconductor device 100 n accordance with the first reference example. Further, the field plate insulating film 61 and the field plate wire 62 are not provided in the semiconductor device 100. However, the drift region 12 described above is provided, instead of a portion in the low concentration region 11 of the semiconductor device 1, in the semiconductor device 100. The other configurations of the semiconductor device 100 are in the same manner as those of the semiconductor device 1. The semiconductor device 100 is formed through the manufacturing process described below.

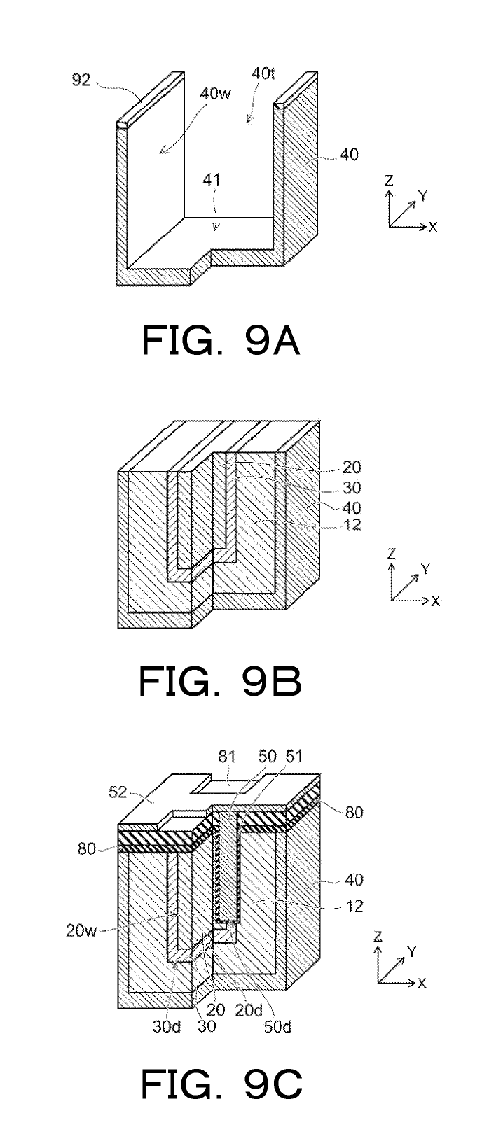

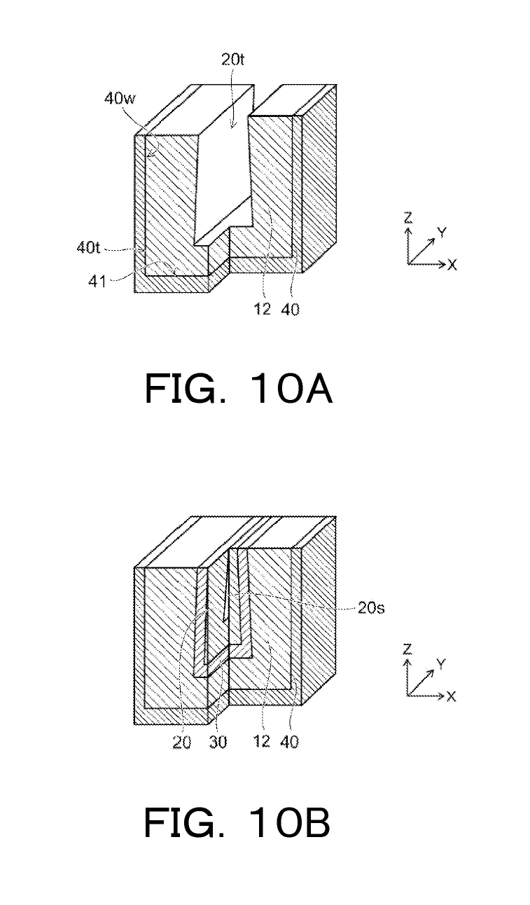

First, the first reference example will be described. FIGS. 9A to 10B illustrate schematic perspective views of the steps of manufacturing the semiconductor device in accordance with the first reference example.

In the first reference example, after preparing the semiconductor wafer configured by the drain region 40, a patterning of a mask 92 on the drain region 40 is performed. Further, an RIE processing is carried out in the drain region 40 opened from the mask 92. FIG. 9A illustrates the state.

As illustrated in FIG. 9A, the drain region 40 in which a trench 40t is provided is formed. A width of the trench 40t in the X direction is wider than that of the trench 10ta in the X direction. In addition, a depth of the trench 40t in the Z direction is deeper than that of the trench 10ta in the Z direction.

As illustrated in FIG. 9B, the drift region 12, the base region 30 and the source region 20 are formed, in the sequence, on a bottom surface 41 and an inside surface 40wa of the trench 40t. The drift region 12, the base region 30 and the source region 20 are formed by using epitaxial growth techniques.

Subsequently, as illustrated in FIG. 9C, the interlayer insulating films 80, 81 are formed on the drain region 40, the drift region 12, the base region 30 and the source region 20. Further, after the etching treatment is carried out in a semiconductor layer opened from the interlayer insulating films 80, 81 to form the trench, the gate insulating film 51 and the gate electrode 50 are formed inside the trench. In addition, the gate wiring 52 is patterned on the interlayer insulating film 81. The semiconductor device 100 in accordance with the first reference example is formed through the manufacturing step.

In the first reference example, a method in which three layers of epitaxial layers (the drift region 12, the base region 30, and the source region 20) are buried in the trench 40t is adopted. Further, a thickness of the drift region 12 initially formed inside the trench 40t is thicker than that of the other epitaxial layers (the base region 30 and the source region 20). Accordingly, a buried state of the drift region 12 greatly affects a buried state of the base region 30 and the source region 20.

For example, there are cases where, in a growth rate of the epitaxial layer, a rate in the vicinity of an opening 40u of the trench 40t is faster than that in the bottom surface 41 of the trench 40t. In the case, the trench 12t which is provided in the drift region 12 is easy to become a so-called reverse tapered state, as illustrated in FIG. 10A. Further, when the base region 30 and the source region 20 are buried in the trench 12t, as illustrated in FIG. 10B, a seam 20s is generated inside the source region 20 in some cases.

In order not to generate the seam 20s, there is a method in which the upper portion of the trench 12t having the reverse tapered state is expanded by etching treatment. For example, the drift region 12 in the state of FIG. 10A is exposed under an atmosphere of hydrogen chloride (HCI) to remove the vicinity of opening of the trench 12t. However, when the method is used, the etching treatment step becomes essential and the manufacturing step is not shortened.

Next, the second reference example will be described. The low concentration region which has a lower concentration of impurities than the drift region 12 may be formed through the manufacturing step described below.

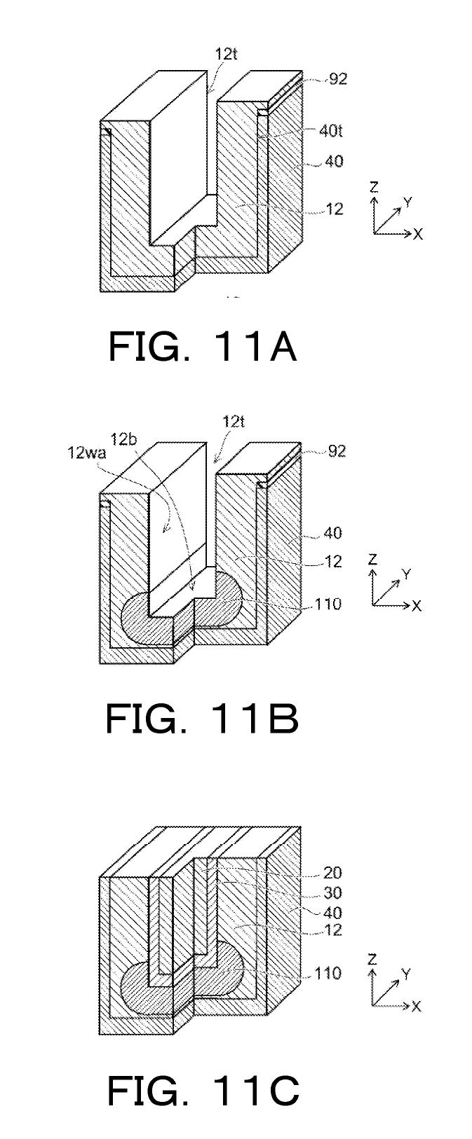

FIGS. 11A to 11C are schematic perspective views illustrating steps of manufacturing a semiconductor device in accordance with the second reference example.

For example, in the same manner as in the first reference example, after the drain region 40 in which the trench 40t is provided is prepared, the drift region 12 is formed on the bottom surface 41 and the inside surface 40wa of the trench 40t. FIG. 11A illustrates the state. The drift region 12 in which the trench 12t is provided is formed without completely burying the drift region 12 into the trench 40t. The drift region 12 is formed by using epitaxial growth techniques.

As illustrated in FIG. 11B, a p-type impurity (boron, for example) are implanted into the bottom surface 12b of the trench 12t and the inside surface 12wa of the drift region 12 adjacent to the bottom surface 12b. The p-type impurity is injected, so that the n-type impurity included in the drift region 12 cancels out by the p-type impurity (counter-ion implantation method), thereby forming an n⁻-type low concentration region 110 having a lower concentration than the drift region 12. The low concentration region 110 covers the bottom surface 12b of the trench 12t and the inside surface 12wa adjacent to the bottom surface 12b.

As illustrated in FIG. 11C, the base region 30 and the source region 20 are formed inside the trench 12t in the sequence. The base region 30 and the source region 20 are formed by using epitaxial growth techniques.

In the second reference example, in order to activate the p-type impurity which is ion-implanted, after the p-type impurity is implanted, it is necessary to carry out the annealing treatment at a high temperature over a long period of time. This is because it is necessary to activate the p-type impurity which is implanted without any limit, to accelerate a counter-ion implantation. Therefore, the annealing treatment is necessary at a high temperature over a long period of time. However, when the annealing treatment is carried out, there is possibility that the n-type impurity in the n⁺-type drain region 40 is easily diffused in the base region 30 through the drift region 12, and the desired concentration profile of impurities may not be obtained in the drift region 12 or the base region 30.

Further, in the second reference example, since the diffusion length of impurities in the annealing treatment is importantly considered, it is not possible to design a pitch of two or more trenches equal to or below the diffusion length. For example, this is because, when the distance between the adjacent trenches 12t becomes equal to or below the diffusion length of impurities, the adjacent low concentration regions overlap each other. For this reason, in the second reference example, a limit is posed in miniaturization of a device. In addition, in an ion-implantation, the concentration of the p-type impurity inside the low concentration region 110 becomes non-uniform in some cases. Thereby, there is possibility that a portion of the low concentration region 110 may be the p-type semiconductor.

On the other hand, the semiconductor device 1 includes the field plate electrode 60 and the low concentration region 11.

In the semiconductor device 1, the parasitic capacitance is further reduced between the gate electrode 50 and the drain region 40, by providing the field plate electrode 60. Therefore, a fast switching is possible in the semiconductor device 1. Further, depletion of the drift region 12 is accelerated during switching off, by providing the field plate electrode 60. Accordingly, compared with a case where the field plate electrode 60 is not provided, the concentration of impurities of the drift region 12 may be set to be high. As a result, compared with the semiconductor device 100, on-resistance of the semiconductor device 1 is decreased.

Further, in the semiconductor device 1, the low concentration region 11 which has a lower concentration of impurities than the drift region 12 is provided in the lower side of the drift region 12 (see FIGS. 1, 2A and 2B). In addition, the low concentration region 11 covers the lower end 30d of the base region 30 and a portion of the side surface 30w of the base region 30 adjacent to the lower end 30d.

As a result, compared with the semiconductor device 100, a depletion layer is easily expanded from the lower end 30d of the base region 30 in the semiconductor device 1. As a result, electric field strength in the vicinity of the lower end of the base region 30 is alleviated compared with the semiconductor device 100. Accordingly, withstand voltage of the semiconductor device 1 is higher than withstand voltage of the semiconductor device 100.

Further, the low concentration region 11 covers the lower end 30d of the base region 30 and a part of the side surface 30w of the base region 30 adjacent to the lower end 30d, and is provided in all the lower side of the drift region 12. The low concentration region 11 is a part of the semiconductor wafer, and the thickness of the low concentration region 11 in the Z direction is uniform. In addition, in the first embodiment, since the annealing treatment at the high temperature over the long period of time after ion-implanted is not necessary, the concentration of impurities of the low concentration region 11 is even compared with the low concentration region 110. Therefore, compared with the low concentration region 110 in accordance with the second reference, the distance of the depletion layer expanded from the base region 30 becomes longer in the low concentration region 11 in accordance with the first embodiment. As a result, withstand voltage of the semiconductor device is further improved.

Further, in the first embodiment, the semiconductor wafer including the three-layered semiconductor region is used and the trench is formed in the semiconductor wafer to epitaxially grow the base region 30 and the source region 20 inside the trench. That is to say, in the first embodiment, it is not necessary to form the drift region 12 as in the first reference example. As a result, in the first embodiment, the seam 20s is hard to generate inside the source region 20. In addition, the manufacturing step is simplified as long as the drift region 12 is not epitaxially grown inside the trench.

Further, in the first embodiment, it is not necessary to form the low concentration region by ion-implanting as in the second reference example. In addition, the annealing treatment after the ion-implantation is also not necessary. Accordingly, the manufacturing step is simplified in the first embodiment, and the low concentration region 11 which has the desired concentration profile of impurities, the drift region 12, and the base region 30 may be formed.

Further, in the first embodiment, without considering the diffusion length of impurities during annealing treatment, the device may be further designed minutely compared with the second reference example. In addition, a portion of the low concentration region 11 is not modified into a p-type semiconductor.

Further, in the first embodiment, a state in which the upper surface 11u of the low concentration region 11 is positioned between the lower end 20d of the source region 20 and the lower end 30d of the base region 30 (referred to as FIGS. 1, 2A and 2B), and a state in which the upper surface 11u of the low concentration region 11 is positioned above the lower end 20d of the source region 20 are included. For further reducing the on-resistance, the former state in which a volume of the drift region 12 may be designed to be larger is more preferable. For further increasing withstand voltage of the semiconductor device, the latter state in which electric field strength in the vicinity of the lower end of the base region 30 is further alleviated is more preferable. Depending on a proper use of the semiconductor device, the depth of the trench 10ta is sufficiently adjusted in the manufacturing step.

Further, in the first embodiment, the state in which the lower end 60d of the field plate electrode 60 is positioned above the upper surface 11u of the low concentration region 11 is more preferable than the state in which the lower end 60d of the field plate electrode 60 is positioned below the lower surface 11d of the low concentration region 11. In addition, the state in which the lower end 60d of the field plate electrode 60 is positioned between the lower surface 11d of the low concentration region 11 and the upper surface 11u of the low concentration region 11 is more preferable than the state in which the lower end 60d of the field plate electrode 60 is positioned above the upper surface 11u of the low concentration region 11.

In the state in which the lower end 60d of the field plate electrode 60 is positioned below the lower surface 11d of the low concentration region 11, the lower end 60d of the field plate electrode 60 is positioned inside the drain region 40b. Therefore, the electric field is concentrated in the lower end 60d of the field plate electrode 60, or the electric field is concentrated in the vicinity of the interface between the drain region 40b and the low concentration region 11. As a result, there is possibility that a limit is posed in an improvement of withstand voltage. As described above, the state in which the lower end 60d of the field plate electrode 60 is positioned above the upper surface 11u of the low concentration region 11 is more preferable than the state in which the lower end 60d of the field plate electrode 60 is positioned below the lower surface 11d of the low concentration region 11.

Further, in a case where the state in which the lower end 60d of the field plate electrode 60 is positioned between the lower surface 11d of the low concentration region 11 and the upper surface 11u of the low concentration region 11 is more preferable than the state in which the lower end 60d of the field plate electrode 60 is positioned above the upper surface 11u of the low concentration region 11, the electric field in the vicinity of the lower end of the field plate electrode 60 is more alleviated. Therefore, the state in which the lower end 60d of the field plate electrode 60 is positioned between the lower surface 11d of the low concentration region 11 and the upper surface 11u of the low concentration region 11 is more preferable than the state in which the lower end 60d of the field plate electrode 60 is positioned above the upper surface 11u of the low concentration region 11.

Further, in the first embodiment, since the lower end 50d of the gate electrode 50 is positioned above the lower end 60d of the field plate electrode 60, electric field concentration to the lower end 50d of the gate electrode 50 is alleviated by the field plate electrode 60. As a result, the reduction in withstand voltage of the field plate insulating film 61 is hard to occur.

Further, the state in which the lower end 50d of the gate electrode 50 is positioned above the lower end 20d of the source region 20 or the state in which the lower end 50d of the gate electrode 50 is positioned below the lower end 30d of the base region 30 is more preferable than the state in which the lower end 50d of the gate electrode 50 is positioned between the lower end 20d of the source region 20 and the lower end 30d of the base region 30. This is because that when the lower end 50d of the gate electrode 50 is positioned between the lower end 20d of the source region 20 and the lower end 30d of the base region 30, the depletion layer expanded inside the base region 30 is blocked by the lower end 50d of the gate electrode 50. When the depletion layer is blocked by the lower end 50d of the gate electrode 50, there is a possibility that the depletion layer is insufficiently expanded inside the base region 30 to cause the reduction in withstand voltage.

In accordance with the first embodiment, the semiconductor device capable of increasing withstand voltage and reducing cost is realized.

### Second Embodiment

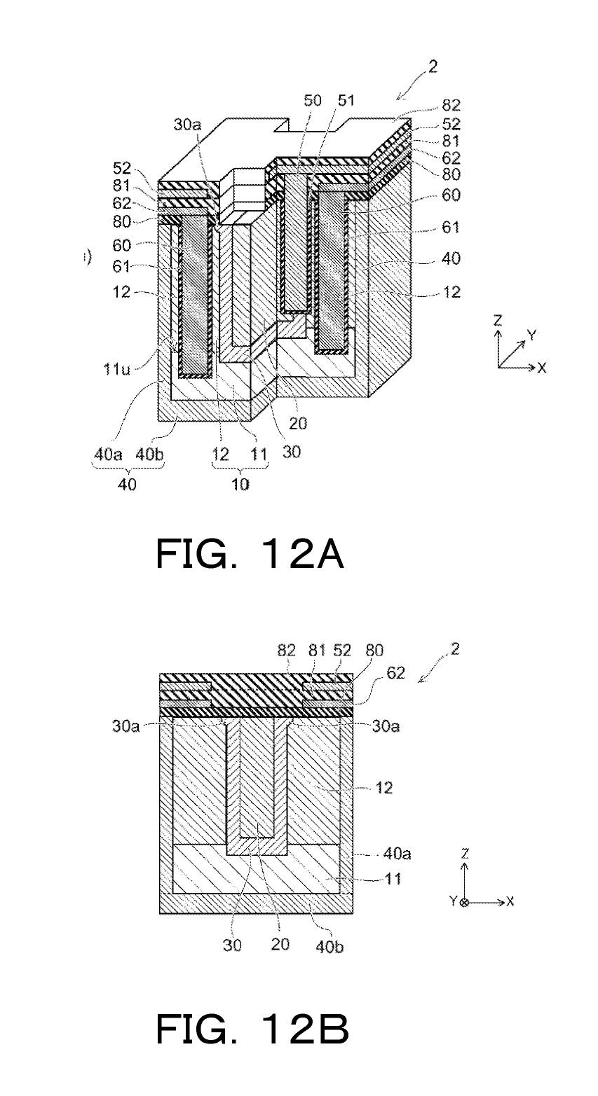

FIGS. 12A and 12B is schematic perspective views illustrating a semiconductor device in accordance with a second embodiment.

A basic structure of a semiconductor device 2 in accordance with the second embodiment is the same as that of the semiconductor device 1 in accordance with the first embodiment. However, the base region 30 of the semiconductor device 2 includes a protrusion 30a which protrudes from the upper end of the base region 30 to the drain region 40a side. The protrusion 30a is the p⁺-type silicon layer. The protrusion 30a is formed by using the ion-implantation, epitaxial growth techniques, or the like, for example.

A pn diode is provided between the protrusion 30a and the drift region 12 by providing the protrusion 30a. As a result, in the semiconductor device 2, surge absorption is accelerated, and thus withstand voltage of the semiconductor device 2 is further improved.

Hereinbefore, the embodiments have been with reference to specific embodiments, but the embodiments are not limited to specific embodiments. That is to say, appropriate variation of the design added to these specific embodiments by the inventors is made within a range of the embodiment as long as characteristics of the embodiment are included. The respective elements, an arrangement of the elements, a material, a condition, a state, and a size included in the respective specific embodiments described above are not limited to those exemplified, but may be appropriately changed.

Further, the respective elements included in the respective embodiments described above may be combined as long as it is technically changeable. The combination of these elements is made within a range of the embodiment as long as characteristics of the embodiment are included. Apart from that, it is understood that, within a range of the gist of the embodiment, those skilled in the art may conceive modifications and variations, and the modifications and variations of the embodiment may be made within a range of the embodiment.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor laminated body including a first semiconductor region of a first conductivity type and a second semiconductor region of the first conductivity type provided on the first semiconductor region and having a higher concentration of impurities than that of the first semiconductor region, the semiconductor laminated body including an inside surface and an outside surface opposed to the inside surface, the first semiconductor region including an upper surface and a lower surface;
a third semiconductor region including a side surface and a lower end, the side surface and the lower end being surrounded by the semiconductor laminated body;
a fourth semiconductor region of a second conductivity type provided between the semiconductor laminated body and the third semiconductor region, the fourth semiconductor region being in contact with the inside surface of the semiconductor laminated body, and including an upper end and a lower end;
a fifth semiconductor region of the first conductivity type being in contact with the outside surface of the semiconductor laminated body;
a first electrode being in contact with the third semiconductor region, the fourth semiconductor region and the second semiconductor region via a first insulating film, and including a lower end;
a second electrode provided between the fourth semiconductor region and the fifth semiconductor region, and including a side surface and a lower surface, the side surface being in contact with the semiconductor laminated body via a second insulating film;
a third electrode electrically connected to the third semiconductor region; and
a fourth electrode electrically connected to the fifth semiconductor region,
wherein the lower end of the second electrode is positioned between the lower surface of the first semiconductor region and the upper surface of the first semiconductor region, and
the upper surface of the first semiconductor region is positioned between the lower end of the third semiconductor region and the lower end of the fourth semiconductor region.

2. The semiconductor device according to claim 1, wherein the lower end of the first electrode is positioned above the lower end of the second electrode.

3. The semiconductor device according to claim 1, wherein the fourth semiconductor region includes a protrusion which protrudes from an upper end of the fourth semiconductor region to the fifth semiconductor region side.

4. A semiconductor device, comprising:
a semiconductor laminated body including a first semiconductor region of a first conductivity type and a second semiconductor region of the first conductivity type provided on the first semiconductor region and having a higher concentration of impurities than that of the first semiconductor region, the semiconductor laminated body including an inside surface and an outside surface opposed to the inside surface, the first semiconductor region including an upper surface and a lower surface;
a third semiconductor region including a side surface and a lower end, the side surface and the lower end being surrounded by the semiconductor laminated body;
a fourth semiconductor region of a second conductivity type provided between the semiconductor laminated body and the third semiconductor region, the fourth semiconductor region being in contact with the inside surface of the semiconductor laminated body, and including an upper end and a lower end;
a fifth semiconductor region of the first conductivity type being in contact with the outside surface of the semiconductor laminated body;
a first electrode being in contact with the third semiconductor region, the fourth semiconductor region and the second semiconductor region via a first insulating film, and including a lower end;
a second electrode provided between the fourth semiconductor region and the fifth semiconductor region, and including a side surface and a lower surface, the side surface being in contact with the semiconductor laminated body via a second insulating film;
a third electrode electrically connected to the third semiconductor region; and
a fourth electrode electrically connected to the fifth semiconductor region.

5. The semiconductor device according to claim 4, wherein the lower end of the first electrode is positioned above the lower end of the second electrode.

6. The semiconductor device according to claim 4, wherein the fourth semiconductor region includes a protrusion which protrudes from the upper end of the fourth semiconductor region to the fifth semiconductor region side.

7. The semiconductor device according to claim 4, wherein the lower end of the second electrode is positioned between the lower surface of the first semiconductor region and the upper surface of the first semiconductor region.

8. The semiconductor device according to claim 7, wherein the lower end of the first electrode is positioned above the lower end of the second electrode.

9. The semiconductor device according to claim 7, wherein the fourth semiconductor region includes a protrusion which protrudes from the upper end of the fourth semiconductor region to the fifth semiconductor region side.

10. The semiconductor device according to claim 7, wherein the upper surface of the first semiconductor region is positioned between the lower end of the third semiconductor region and the lower end of the fourth semiconductor region.

11. The semiconductor device according to claim 10, wherein the fourth semiconductor region includes a protrusion which protrudes from the upper end of the fourth semiconductor region to the fifth semiconductor region side.

12. The semiconductor device according to claim 10, wherein the lower end of the first electrode is positioned above the lower end of the second electrode.

13. The semiconductor device according to claim 12, wherein the fourth semiconductor region includes a protrusion which protrudes from the upper end of the fourth semiconductor region to the fifth semiconductor region side.

14. A method of manufacturing a semiconductor device, comprising:
forming a trench with a bottom surface and an inside surface in a semiconductor laminated body including a first semiconductor region of a first conductivity type and a second semiconductor region of the first conductivity type provided on the first semiconductor region and having a higher concentration of impurities than that of the first semiconductor region;
forming a fourth semiconductor region of a second conductivity type and a third semiconductor region of the first conductivity type on the bottom surface of the trench and the inside surface of the trench, in the order;
forming a fifth semiconductor region of the first conductivity type in contact with an outside surface of the semiconductor laminated body opposite to an inside surface of the semiconductor laminated body, the inside surface being in contact with the fourth semiconductor region;
forming a second electrode between the fourth semiconductor region and the fifth semiconductor region so as to have the side surface in contact with the semiconductor laminated body via a second insulating film;
forming a first electrode in contact with the third semiconductor region, the fourth semiconductor region and the second semiconductor region through a first insulating film; and
forming a third electrode electrically connected to the third semiconductor region and a fourth electrode electrically connected to the fifth semiconductor region.

15. The method of manufacturing the semiconductor device according to claim 14, wherein the forming of the second electrode is performed by forming a trench with a bottom surface and an inside surface in the semiconductor laminated body, forming the second insulating film on the bottom surface and the inside surface of the trench, and forming a conductive material inside the trench.

16. The method of manufacturing the semiconductor device according to claim 15, further comprising:
carrying out a heat treatment of the second electrode.

17. The method of manufacturing the semiconductor device according to claim 14, wherein the forming of the first electrode is performed by forming a trench with a bottom surface and an inside surface in contact with the third semiconductor region, the fourth semiconductor region and the second semiconductor region, forming the first insulating film on the bottom surface and the inside surface of the trench, and forming a conductive material inside the trench.

18. The method of manufacturing the semiconductor device according to claim 17, further comprising:
carrying out a heat treatment of the first electrode.
